(19) United States
(12) Patent Application Publication
(10) Pub. No.: US 2002/0093089 A1
(43) Pub. Date: Jul. 18, 2002

(54) COMPLIANT MOUNTING INTERFACE FOR ELECTRONIC DEVICES

(76) Inventors: DAU-TSYONG LU, CLIFTON PARK, NY (US); JOHN T. KEATING, CLIFTON PARK, NY (US)

Correspondence Address: MARK LEVY, SALZMAN & LEVY, 19 CHENANGO ST, STE 606, BINGHAMTON, NY, 13901

(21) Appl. No.: 09/452,833

(22) Filed: Dec. 1, 1999

(51) Int. Cl. H01L 23/02

(52) U.S. Cl. 257/700

(57) ABSTRACT

The present invention features apparatus and a method for forming a highly-compliant interface structure between interconnection pads on a substrate, such as a printed circuit board, and a semiconductor chip. A thin dielectric layer is deposited over an interconnection pad. A metallized pattern is deposited over the dielectric layer, the pattern typically being a rectangular grid, concentric, annular rings, or a wave-like spiral. A portion of the dielectric layer may be removed from beneath at least a portion of the metallized pattern, thereby allowing flexing of the metallized pattern. A solder mask may be placed over the metallized pattern. Finally, a solder ball or epoxy for forming a typical BGA bond is placed at an opening in the solder mask. Unequal thermal expansion of the substrate and the chip are thereby compensated for by lateral and/or vertical flexure of the metallized grid. Thermal stress of the solder connection and resultant cracking are thereby eliminated. In alternate embodiments, the dielectric layer may be pre-formed into a rippled, wave-like pattern prior to deposition of the metallized pattern to improve vertical flexure of the metallized pattern. In addition, methods for forming both complaint vias and conductive buttons are shown.

### FIELD OF THE INVENTION:

This invention pertains to interface structures for mounting electronic devices and, more particularly, to flexible interface structures to minimize mechanical stress caused by different coefficients of thermal expansion between an electronic device such as a semiconductor, printed circuit board, multi-chip module, etc. and a substrate or another electronic device.

### BACKGROUND OF THE INVENTION

As electronic products continue to shrink in both size and weight, increasing demands are placed upon the electrical structures which implement the necessary electronic circuits. In portable electronic devices, the weight of the battery contributes a high percentage of the overall device weight so that even greater demands are made for engineers to reduce bulk and weight of other components. In one typical industry, cellular phone manufacturers are currently faced with the challenge of developing a phone, the total weight of which is under 50 grams. As a result, structures have been developed which maximize the level of component integration while minimizing both the overall weight and footprint (i.e., device size) of sub-assembly components. While there have been numerous advances made in this area, several problems still face the industry.

The shrinking of both electronic devices, such as circuit modules, and their mounting means has resulted in a reduction of system reliability. This reliability decrease has often been caused by failure of electrical connections between an electronic device and the substrate upon which it is mounted. To counter this problem, expensive underfill materials have been used in an attempt to relieve thermally-induced stresses resulting from mismatched coefficients of thermal of expansion (CTE) of the electronic device and the substrate.

Ball grid array (BGA) technology has heretofore been the technology of choice for providing high density interconnections between semiconductor devices, interposer structures and other similar structures, and a mounting substrate such as a printed circuit board (PCB). BGA provides a great number of connections per unit area, but mismatches of coefficients of thermal expansion occur when ceramic or polymer BGA substrates and PCBs are joined, often resulting in cracked solder joints. This has become more prevalent as the size of the substrates and operating temperature ranges have increased.

In column grid array (CGA) techniques and other BGA techniques, a eutectic solder is applied to PCBs and multi-chip module array pads. The resulting joint is soldered to a higher temperature solder column or ball which does not melt.

Both BGA and CGA structures can be inflexible and vulnerable to damage. For various types of BGA and CGA, increases in reliability are attempted by elaborate under-filling of the structures with polymer glues to reinforce the interfaces and reduce the effects of the CTE mismatch of the solder joints. These polymer glues, however, impair repairability because of the difficulty in removing the glues after hardening. Furthermore, these types of structures require two separate solder steps, are more expensive than conventional solder structures, and require more vertical space due to increased height of the joints.

One conventional micro ball grid array interface technique for attaching a semiconductor circuit chip or other microelectronic structure directly to a substrate is to use a series of solder bumps clustered at the center of the chip. This technique constrains the area over which stresses occur due to differing coefficients of thermal expansion. In this embodiment, chips have their pads reconfigured and solder micro bumps are applied over the reconfigured pads. In one embodiment, in an effort to avoid CTE stress effects, ball grid array processes are used with the temperature range being constrained during device operation between 30° C. and 70° C. In another ball grid array interface technique, the area where the chip faces the PCB or substrate is not used for direct interconnection. Instead, metallization is routed from the chip to adjacent support structures which then have solder ball connections. This technique can create size and pin count limitations, as well as electrical parasitic effects.

There have been a number of highly compliant interfaces developed for microelectronic application. One such development is the elastomer-based micro BGA. This consists of an elastomer and a flexible circuit placed directly over the surface of an electronic packaging structure such as a semiconductor die or other semiconductor package. The elastomer provides a compliant interface between the semiconductor die and its mating substrate. The primary problem with the micro BGA approach is that in order to maintain acceptable electrical characteristics, the elastomer must remain very thin. This thinness of the elastomer material limits the amount of yield available in a lateral direction. In addition, a relatively high compressive force must be applied to form the electrical connection. Under certain manufacturing conditions, this high compressive force may not be possible.

Another approach is to employ a microspring like structure formed from the break-off wire in a conventional wire bonding process. The wire is plated with a resilient material such as Nickel, which helps maintain the elasticity of the wire spring. This approach is limited by the physical resolution of the wire bonding machine. In addition, there is only a single point of contact between the microspring and either the semiconductor device or the substrate. This singlepoint contact may introduce electrical contact reliability problems and may also introduce microphonic noise under mechanical vibration.

U.S. Pat. No. 5,900,674 for INTERFACE STRUCTURES FOR ELECTRONIC DEVICES, issued May 4, 1999 to Robert John Wojnarowski, et al., provides one solution to these aforementioned problems. WOJNAROWSKI, et al. describe an interface including a surface having an electrically conductive pad; a compliant coating over the surface having a via extending to the pad; metallization patterned over the compliant coating and extending into the via; a low modulus dielectric interface layer overlying the compliant coating and having an interface via extending to the metallization; and a floating pad structure including floating pad metallization patterned over the dielectric interface layer. A first portion of the pads forms a central pad and a second portion is an extension from the central pad into the interface via. The extension provides stress relief for different coefficients of thermal expansion.

In contradistinction, the structure of the present invention does not rely on an extension from a via to compensate for mismatches in CTEs between electronic devices and substrates such as PCBs. The inventive structure features a compliant, spring-like structure for insertion between the PCB and the electronic device. Sufficient compliance is available in three planes so that thermally induced movement of the electronic component relative to the substrate may be accommodated easily.

### SUMMARY OF THE INVENTION

In accordance with the present invention, there is provided a highly-compliant, electrically conductive structure for establishing an electrical connection between an electronic device, especially a semiconductor device, and a substrate such as a printed circuit board. Because coefficients of thermal expansion of the two devices are sometimes different, stress develops in rigid electrical connections. The present invention provides multiple embodiments of a highly-compliant grid structure designed to form an interface between an electronic device and a substrate to which the device is mounted. The need for underfill is eliminated when the compliant grid of the instant invention is utilized.

It is, therefore, an object of the invention to provide a more flexible interface structure for electronic devices, one that does not require underfilling.

It is an additional object of the invention to provide an interface structure that can be used for relieving stress from a wide variety of electronic components such as multi-chip modules (MCMs), wafers, individual dies or bare chips, microelectromechanical structures (MEMs), printed circuit boards (PCBs), printed wiring boards (PWBs) and surface mount packages.

It is yet another object of the invention to provide an interface structure for relieving stresses caused by coefficient of thermal expansion mismatches with connections such as those formed by ball grid arrays, micro ball grid arrays, column grid arrays, flip chips, solder joints, or tape automated bonding connections.

### BRIEF DESCRIPTION OF THE DRAWINGS

A complete understanding of the present invention may be obtained by reference to the accompanying drawings, when considered in conjunction with the subsequent, detailed description, in which:

FIG. 1a is a plan view of a first embodiment of the compliant grid of the invention:

FIG. 1b is a plan view of a second embodiment of a compliant grid of the invention;

FIG. 2a shows a cross-sectional view of the compliant grid shown in FIG. 1a;

FIG. 2b shows a cross-sectional view of an alternate embodiment of the compliant grid of the invention, having a wave-like pattern;

FIG. 3a is a plan view of a first via location for use in conjunction with the compliant grid of the invention;

FIG. 3b is a plan view of an alternate via location for use with the compliant grid of the invention;

FIG. 4 is a perspective view of the compliant grid structure of the invention;

FIG. 5 is a cross-sectional view of the compliant grid of the invention;

FIG. 6 is a perspective view of a third embodiment of the compliant grid of the invention;

FIG. 7 is a cross-sectional view of the compliant grid shown in FIG. 6;

FIG. 8a is a cross-sectional view of a compliant via having a single dielectric layer;

FIG. 8b is a cross-sectional view of a compliant via having a multi-layer dielectric;

FIG. 9a is a cross-sectional view of a complaint connector button in accordance with the invention; and

FIG. 9b is a cross-sectional view of an alternate embodiment of the compliant button of FIG. 9a.

For purposes of both clarity and brevity, like elements and components will bear the same designations and numbering throughout the figures.

### DESCRIPTION OF THE PREFERRED EMBODIMENT

Generally speaking, the invention features an electrically-conductive interface structure for insertion between an electronic device and a substrate and, more particularly, to a flexible interface structure for insertion between an electronic device and a substrate for relieving mechanical stresses caused by mismatched coefficients of thermal expansion of the two components being joined. In addition, the inventive structure absorbs vibration from external sources thereby reducing contact failure from vibration induced stress.

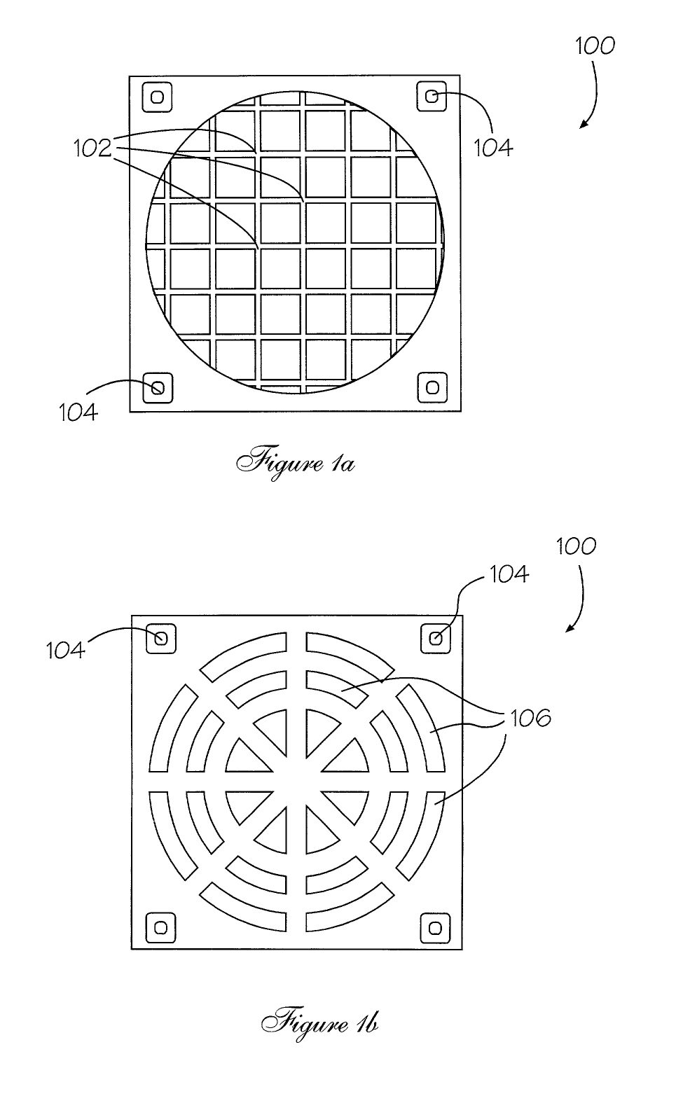

Referring first to FIG. 1a, there is shown a plan view of a first embodiment of a highly-compliant, electrically conductive grid structure 100 for establishing reliable electrical connections between electronic devices, such as semiconductor chips, and substrates. For purposes of disclosure, the term “chip” is used to refer to any microelectronic structure, particularly semiconductor devices, packaged, bare die, or in any other form including uncut wafers, multi-chip modules (MCM), chip-scale packages (CSP) as well as printed circuit boards, printed wiring boards or the like. The term “substrate” is likewise used to refer to any surface upon which the chip or other structure may be mounted, such as printed circuit boards (PCBs), sockets, interposers, flex circuits or other substrates. The inventive structure is also useful for joining like structures such as PCB to PCB, etc.

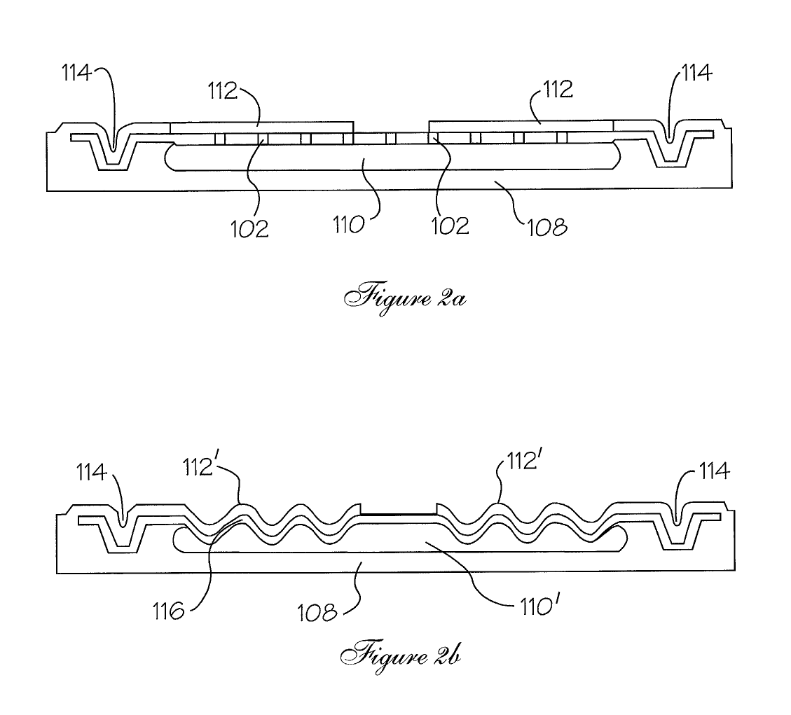

Grid 100 consists of a metallized pattern 102 formed on top of a dielectric layer 110 (FIG. 2a). A thin layer of dielectric material, typically a polymer such as Kapton E® manufactured by DuPont, is laminated, coated, or otherwise deposited on the chip and/or substrate. Typically, chemical etching, plasma etching, reactive ion beam or laser ablation are used to form metallized pattern 102, but any other technique known to those skilled in the art could also be employed. After formation of metallized pattern 102, four via locations 104 are shown spaced around metallized pattern 102. In alternate embodiments, air may be used as a dielectric with metallized pattern 102 being self-supporting. The number of via location 104 may vary depending upon the application and the actual number forms no part of the present invention.

Referring now also to FIG. 1b, there is shown another possible metallized pattern 106. Via locations 104 are also present. It should be noted that many different metallization patterns may be used; the invention is not considered to be limited to the two patterns shown in FIGS. 1a and 1b for purposes of disclosure.

Referring now to FIG. 2a, there is shown a cross-sectional view of the highly-compliant grid structure as shown in FIG. 1a. A layer of dielectric 110 is shown deposited on component mounting pad 108. Metallized pattern 102 is formed on top of dielectric layer 110. A solder mask 112 is formed on top of metallized pattern 102. Two vias 114 are also shown.

Referring now to FIG. 2b, there is shown a cross-sectional view of an alternate embodiment of the highly complaint grid of the invention. In this embodiment, dielectric layer 110′ has been pre-formed with a wave-like pattern prior to the formation of a metallized grid pattern 116 thereupon. Solder mask 112′ is shown on top of metallized grid pattern 116. Vias 114 are also shown. This embodiment with the wave-like configuration provides for compliance in a small space to compensate for stresses at vias 114 cause by movement of a chip (not shown) relative to a substrate 108 caused by unmatched coefficients of thermal expansion.

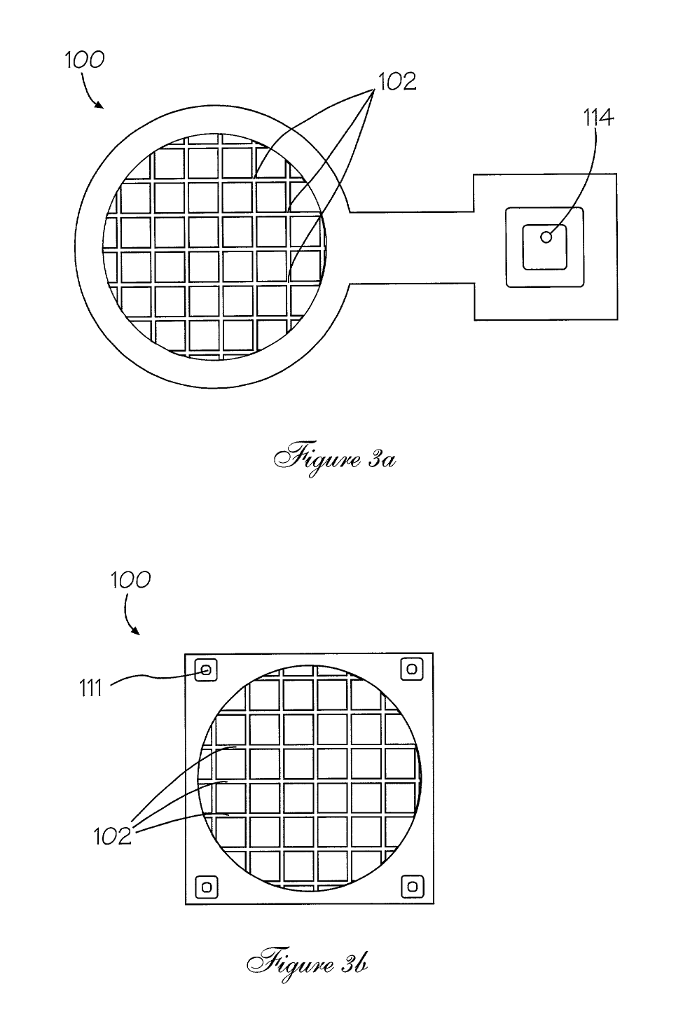

Referring now to FIGS. 3a and 3b, there are shown two possible locations of vias 114 relative to the inventive compliant grid. In the embodiment shown in FIG. 3a, via 114 is located at a separate pad area 118 separated from grid 100. In the alternate embodiment shown in FIG. 3b, vias 114 are located at the four corners of compliant grid 100.

Referring now to FIG. 4, there is shown a perspective view of the highly-compliant grid of the present invention wherein the metallized grid 102, vias 114 and dielectric material 110 may be clearly seen.

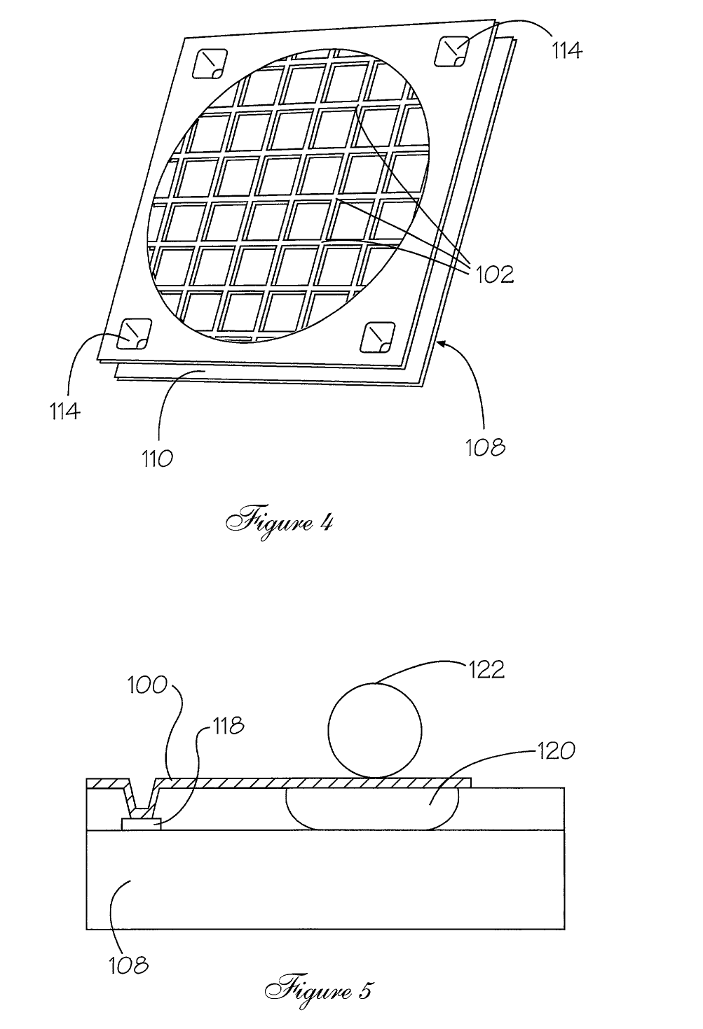

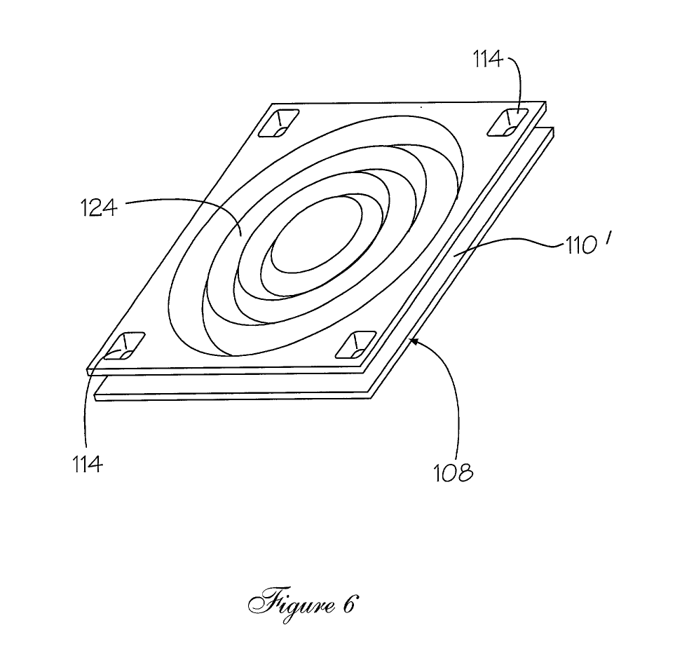

Referring now to FIG. 5, there is shown a cross-sectional view of a typical interconnect using the highly-compliant array of the invention. The substrate material 108 has an interconnect pad 118 located on top. Dielectric material 110 supports compliant grid 100. A region 120 in dielectric material 110 is filled with either a highly-complaint dielectric material or possibly, in some embodiments, with air. A solder ball 122 is positioned over a central portion of compliant grid 100. The combination of compliant grid 100 and the dielectric area 120 allows for movement of solder ball 122 as the chip or substrate (not shown) attached to substrate 108 moves, due to thermal expansion and contraction. The ability of the inventive structure to absorb these thermally-generated movements minimizes and, in most cases, virtually eliminates the possibility of thermal stress-generated contact failure. In alternate embodiments, solder ball 122 may be replaced with another electrically-conductive material such as silver-filled epoxy.

In yet another alternate embodiment, complaint grid 100 may be plated to form a highly-compliant, vertical contact system.

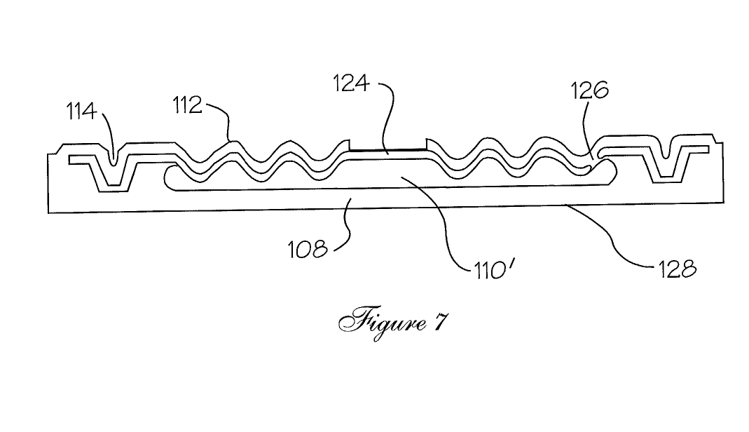

Referring now to FIG. 6, a perspective view of an embodiment of the compliant grid of the instant invention is shown adapted to absorb both lateral as well as vertical movement in a connection between a substrate and a chip. The design of the grid is a wave-like, spiral (annular) structure 124 resembling a ripple on a water surface. Like embodiments previously discussed, spiral 124 is formed as a metallized layer on top of a dielectric layer 110′ deposited over substrate 108.

Reffering now also to FIG. 7, dielectric layer 110′ is pre-formed into a rippled, wave-like pattern prior to the deposition of spiral 124. The spiral 124 structure exhibits improved flexure in the vertical plane, thereby further helping to reduce thermal stress-induced solder joint failures.

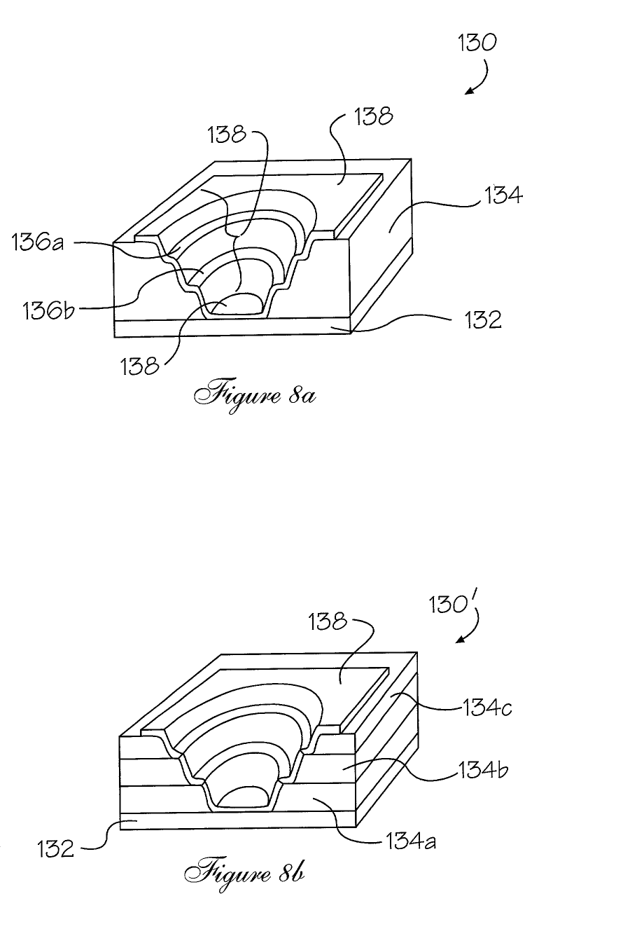

Referring now to FIG. 8a, there is shown a cross-sectional view of a compliant via structure 130 built in a similar manner to the compliant interface of the invention. A dielectric layer 134 is deposited over the I/O pads 132 of a substrate or microelectronic device. By using laser or performing another ablation technique, dielectric 134 is selectively cut away to form a series of ledges or step-like structures 136a, 136b in dielectric material 134. A layer of metal 138 or other conductive material is deposited over dielectric layer 134, so as to form the stepped regions 136a, 136b leaving a complaint via structure.

Referring now to FIG. 8b, there is shown a cross-sectional view of an alternate embodiment of the complaint via 130′ shown in FIG. 8a as reference numeral 130. Three layers of dielectric material 134a, 134b, 134c are successively deposited over the I/O pads 132 of a substrate or microelectronic device. Each successive layer of dielectric 134a, 134b, 134c is deposited such that the opening therein is successively larger than that of the layer below it. Finally, a metal layer 138 is deposited over the built-up dielectric material layers 134a, 134b, 134c. This procedure may yield a manufacturing cost advantage over the aforementioned method of depositing a single layer of dielectric 134 (FIG. 8a) and then using laser ablation or other suitable technique to form the stepped areas 136a, 136b.

The number of steps 136a, 136b formed by laser ablation or formed by building up successive layers of dielectric may be varied according to the need for compliance in different applications and environments. The actual number of steps employed forms no part of the instant invention.

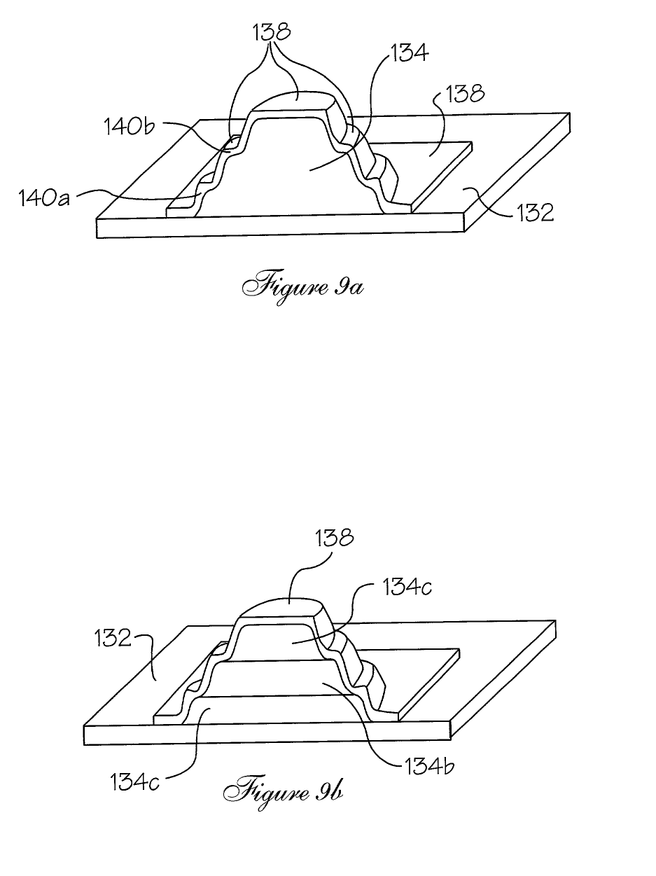

Referring now to FIG. 9a, there is shown a compliant connector button formed in a similar manner to the conductive vias 130, 130′ described hereinabove. A layer of dielectric material 134 is deposited on the I/O pads 132 of a substrate or microelectronic device. Laser ablation or another suitable technique known to those skilled in the art is used to form a series of steps 140a, 140b. While two steps are shown for purposes of disclosure, the number of steps 140a, 140b will depend on the operating environment and circumstances. Finally, a metal layer 138 is deposited over the stepped dielectric layer 134 forming a complaint, conductive connector button.

Referring now to FIG. 9b, there is shown a compliant connector button formed by successively depositing a number of dielectric layers 134a, 134b on the I/O pads 132 of a substrate or microelectronic device. By forming successive layers 134a, 134b sightly smaller that the underlying layers, a series of steps 140a, 140b are formed. This process eliminates the need for laser ablation or forming techniques to form steps 140a, 140b. While only two steps 140a and 140b are shown for purposes of disclosure, the number of steps will depend on the operating environment and circumstances. Finally, a metal layer 138 is deposited over the stepped dielectric 134a-134c forming a complaint, conductive connector button.

Since other modifications and changes varied to fit particular operating requirements and environments will be apparent to those skilled in the art, the invention is not considered limited to the example chosen for purposes of disclosure and covers all changes and modifications which do not constitute departures from the true spirit and scope of this invention.

Having thus described the invention, what is desired to be protected by Letters Patent is presented in the subsequently appended claims.

What is claimed is:

1. A method for electrically and mechanically joining an electronic device to a substrate, the steps comprising:
a) providing a substrate suitable for receiving an electrical contact of an electronic device, said substrate having at least one interconnect pad on a surface;
b) selectively depositing a layer of dielectric material over said surface;
c) depositing an electrically conductive pattern over said dielectric layer;
d) removing a portion of said dielectric layer beneath a predetermined region of said electrically conductive pattern;
e) forming a solder mask over a portion of said electrically conductive pattern;
f) placing electrically conductive material over said solder mask proximate a predetermined region of said electrically conductive pattern; and
g) placing an electrical contact of said electronic device in contact with said electrically conductive material;
whereby a compliant electrical connection is formed between said interconnect pad and said electrical contact and whereby movement of said electrical contact relative to said interconnect pad is absorbed by said electrically conductive pattern.

2. The method for electrically and mechanically joining an electronic device to a substrate as recited in claim 1, wherein said depositing step (c) comprises placing a solder ball over said solder mask and further comprises the step of:
h) reflowing said solder ball.

3. The method for electrically and mechanically joining an electronic device to a substrate as recited in claim 1, wherein said removing step (d) comprises filling at least a portion of a space created by replacing said portion of said dielectric material with a second, compliant dielectric material.

4. The method for electrically and mechanically joining an electronic device to a substrate as recited in claim 1, wherein said depositing an electrically conductive pattern over said dielectric layer step (c) comprises depositing a metallized grid pattern.

5. The method for electrically and mechanically joining an electronic device to a substrate as recited in claim 4, wherein said grid pattern comprises a rectangular lattice pattern.

6. The method for electrically and mechanically joining an electronic device to a substrate as recited in claim 1, wherein said depositing an electrically conductive pattern over said dielectric layer step (c) comprises depositing an intermittent, concentric, annular metallized pattern.

7. The method for electrically and mechanically joining an electronic device to a substrate as recited in claim 1, wherein said depositing an electrically conductive pattern over said dielectric layer step (c) comprises depositing a spiral, wave-like metallized pattern.

8. A compliant interface for resiliently joining two electrical components, comprising:
a) a layer of dielectric material disposed on an interconnection pad on a surface of an electrical component;
b) an electrically conductive pattern disposed on and supported by said dielectric layer; and
c) a cavity in said dielectric layer proximate a predetermined portion of said electrically conductive pattern.

9. The compliant interface for resiliently joining two electrical components as recited in claim 8, further comprising:
d) a solder mask disposed over at least a portion of said electrically conductive pattern.

10. The compliant interface for resiliently joining two electrical components as recited in claim 8, wherein said cavity is at least partially filled with a second, compliant material.

11. A compliant interface component for joining two electrical components, comprising:
a) a layer of dielectric material disposed on an interconnection pad on a surface of an electrical component;
b) an electrically conductive pattern disposed on and supported by said dielectric layer; and
c) a compliant region in said dielectric layer proximate a predetermined portion of said electrically conductive pattern.

12. The compliant interface for joining two electrical components as recited in claim 11, wherein said electrically conductive pattern comprises a metallized grid pattern.

13. The compliant interface for joining two electrical components as recited in claim 12, wherein said grid pattern comprises a rectangular lattice pattern.

14. The compliant interface for joining two electrical components as recited in claim 11, wherein said electrically conductive pattern comprises an intermittent, concentric, annular metallized pattern.

15. The compliant interface for joining two electrical components as recited in claim 11, wherein said electrically conductive pattern comprises a spiral, wave-like metallized pattern.

16. The compliant interface for joining two electrical components as recited in claim 11, wherein said compliant region comprises an gas-filled cavity.

17. The compliant interface for joining two electrical components as recited in claim 11, wherein said compliant region comprises an altered region in said dielectric material.

18. The compliant interface for joining two electrical components as recited in claim 17, wherein said altered region comprises a chemically-altered region.

19. A method for forming a compliant via structure, the steps comprising:
a) providing at least one conductive pad upon which a via is to be formed;
b) depositing a layer of dielectric over said conductive pad;
c) forming at least one step in said layer of dielectric material; and
d) depositing a conductive layer over the stepped surface of said dielectric material.

20. The method for forming a compliant via structure as recited in claim 19, wherein said forming step (c) comprises ablating said dielectric material.

21. The method for forming a compliant via structure as recited in claim 20, wherein said ablating said dielectric material comprises ablating said dielectric material with a laser or other ablation techniques.

22. A method for forming a compliant via structure, the steps comprising:
a) providing at least one conductive pad upon which a via is to be formed;
b) depositing a first layer of dielectric material over said conductive pad, said first layer having a predetermined region with a first dimension;
c) depositing a second layer of dielectric material over said first layer of dielectric material, said second dielectric material having a predetermined region with a second dimension greater than said first dimension such that a stepped dielectric structure is formed; and
d) depositing a conductive layer over said stepped is dielectric structure.

23. A method for forming a compliant, conductive button, the steps comprising:
a) providing at least one conductive pad upon which a conductive button may be formed;
b) depositing a layer of dielectric material over said conductive pad;
c) forming at least one step in said layer of dielectric material; and
d) depositing a conductive layer over said stepped surface of said dielectric material.

24. The method for forming a compliant via structure as recited in claim 23, wherein said forming step (c) comprises ablating said dielectric material.

25. The method for forming a compliant via structure as recited in claim 24, wherein said ablating said dielectric material is performed with a laser or other ablation techniques.

26. A method for forming a compliant via structure, the steps comprising:
a) providing at least one conductive pad upon which a via is to be formed;
b) depositing a first layer of dielectric material over said conductive pad, said first layer having a predetermined region with a first dimension;
c) depositing a second layer of dielectric material over said first layer of dielectric material, said second dielectric material having a predetermined region with a second dimension greater than said first dimension such that a stepped dielectric structure is formed; and
d) depositing a conductive layer over said stepped dielectric structure.
